(19) United States
(12) Patent Application Publication
(10) Pub. No.: US 2002/0178417 A1
(43) Pub. Date: Nov. 28, 2002

(54) Communication channel optimization using forward error correction statistics

(76) Inventors: John M. Jacob, Bedford, MA (US); Katherine L. Hall, Westford, MA (US); Michael J. LaGasse, Lexington, MA (US); Geoffrey B. Ladwig, Chelmsford, MA (US); Morris P. Kesler, Bedford, MA (US)

Correspondence Address: Steven M. Mills, MILLS & ONELLO LLP, Eleven Beacon Street, Suite 605, Boston, MA, 02108, US

(21) Appl. No.: 09/863,043

(22) Filed: May 22, 2001

(51) Int. Cl. G06F 11/00; H03M 13/00

(52) U.S. Cl. 714/752; 714/704

(57) ABSTRACT

An apparatus and method for dynamically optimizing performance in a communication channel are described. The communication channel can be part of a high-speed digital network such as the Internet and can be a dense wavelength-division multiplexed (DWDM) optical communication channel. The DWDM signal includes forward error correction (FEC) information which is added to the DWDM signal and is used within the DWDM optical layer to monitor transfer errors in the data. Error correction statistics generated as a result of analysis of the FEC information in the data in accordance with the invention are used in generating an adjustment to and/or optimizing performance of the system. An adjust signal used in generating and making the adjustment is generated using FEC error correction statistics. In one embodiment, the adjust signal is a feedback signal transferred back to the transmission end of the channel. Each DWDM signal can carry an optical or electronic time-division multiplexed (TDM) combined signal of multiple subsignals. Each subsignal can include its own FEC information. The adjustment made via the adjust signal can include adjusting power level in one or more of the subsignal transmitters. As a result, performance of the system and the network can be optimized dynamically based on an analysis of actual data transfer errors detected in the optical DWDM layer.

### BACKGROUND OF THE INVENTION

High-speed digital data networks such as the Internet include a highly complex system of communication channels for transferring data. In such systems, data is transferred over multiple communication channels. In each channel, data is transferred from an input end to an output end of the channel. A transmission system at the input end formats the data and forwards it onto the channel. A reception system at the output end receives the data and processes it appropriately.

Networks can be considered to be configured as hierarchical tree structures with a trunk or core and many smaller branches. The amount of data carried over a network increases with proximity to the core. At the edges, relatively small bandwidth is required, while at the core, extremely large amounts of data can be carried for long distances over channels with very high bandwidth. The hardware and transfer protocol used at different levels varies according to bandwidth demand. For example, near the edges of the Internet, traffic may be forwarded on electrical lines using the Internet Protocol (IP) or optically using SONET (Synchronized Optical Network). At other higher-level stages, the data can be transferred using a protocol such as SONET or SDH (Synchronized Digital Hierarchy) or ATM (Asynchronous Transfer Mode).

At or near the core of a network, large amounts of data can be transferred optically using dense wavelength-division multiplexing (DWDM). DWDM allows multiple optical carrier signals of different wavelengths to be carried over a single optical fiber. Each optical signal has a separate wavelength, and the multiple signals are combined by wave-division multiplexing into a single optical signal which is transferred over a single optical fiber. With multiple fibers each carrying multiple optical carrier signals, the DWDM optical system provides very high data transfer bandwidth.

It is often desirable to monitor performance of communication channels and make adjustments to optimize performance wherever possible. In particular, monitoring and optimizing performance in the DWDM layer is very important because of the large amounts of data being carried. In prior DWDM systems, performance monitoring and optimization focus solely on the quality of the optical carriers being transmitted. For example, optical signal-to-noise ratio (OSNR) can be monitored and the signal power adjusted to maximize the OSNR. However, maximizing OSNR does not necessarily achieve optimal performance in a channel. For example, where the goal is to minimize data transfer errors, maximization of OSNR may not be the best approach.

Under transfer protocols such as the SONET and IP protocols, data is transferred in frames or packets, each of which includes a data or payload portion and a header portion. The header portion contains the information or “overhead” required to deliver the payload of the frame or packet to its destination. It may also include additional information related to an error correction technique, such as forward error correction (FEC), used to detect and correct errors in the data. The payload portion may also include FEC bits for performing error correction. Error correction techniques such as FEC typically examine a transmitted frame or packet to verify that all of its bits are correct. If they are not, the incorrect bits are replaced with corrected values. FEC can be used with any kind of packet or framing structure in addition to SONET and IP.

Typical FEC chips keep track of the number of bits that are corrected. This data may be grouped and manipulated to give the number of errors of particular types corrected. That is, the data may be grouped to identify the number of errors in one bits and/or zero bits. Also, the number of corrected bits may be compared to the number of uncorrected bits, and bit error rates (BERs) may be calculated. This data is often referred to as FEC statistics, and the FEC statistics may be used to characterize how the channel is performing.

### SUMMARY OF THE INVENTION

The present invention is directed to a communication system and a method for adjusting performance of the communication system, for example, a communication link in a DWDM system. The communication system includes at least one communication channel, and data is forwarded from an input end to an output end of the channel. The data includes a forward error correction (FEC) portion which is used to determine if an error has occurred in the data being transferred. Error correction statistics which are related to errors detected in the data are monitored. Based on the monitored error correction statistics, an adjust signal is generated and is used to generate and make an adjustment in the communication system to adjust performance of the communication system.

The adjust signal can be used to make an adjustment at the input end of the channel, at the output end of the channel or at both ends. For example, the adjustment can be made to transmit equipment at the input end, or to receive equipment at the output end or to both the transmit and receive equipment.

In one embodiment, the adjust signal is a feedback signal which is sent from the output end of the communication channel to the input end of the communication channel. The feedback signal can be sent on a control channel associated with the communication channel. In one embodiment, the adjust signal includes a communication message formatted in accordance with a communication protocol. For example, the message can be an IP message or a SONET message, or a combination of some known protocols, e.g., IP-over-SONET.

In one embodiment, the error correction statistics include bit error rate (BER) for the data. The BER statistics are used in accordance with the invention in generating and making the desired adjustment to reduce BER.

The data can be forwarded over the channel in a DWDM format. That is, the communication channel can be part of a DWDM optical communication system, such as that found at the core of the Internet. The DWDM equipment in accordance with the invention can receive the data for transmission over the channel. In accordance with the invention, the FEC portion of the data can be added to the signal and then formatted and transmitted over the DWDM channel. At the receive or output end of the channel, the DWDM equipment in accordance with the invention can analyze the FEC portion added to the data. The errors detected in the FEC portion of the data are used to generate the error correction statistics. In accordance with the processing of the invention, the error correction statistics are then analyzed to make the adjustment to the system. This can involve generating the feedback signal to be sent back to the transmit end of the channel to make an adjustment to the transmit equipment. It can also include generating a control signal to make an adjustment at the receive equipment.

In one embodiment, the feedback signal sent to the transmit end of the channel includes a report of BER computed at the receive end using the FEC statistics. At the transmit end, an adjustment can be made to the transmit equipment in an effort to improve, i.e., reduce, BER. When the transmit end receives the feedback signal reporting updated BER, a decision is made as to whether the previous adjustment was correct and whether further adjustments should be made. The process of making adjustments and processing feedback from the receive end of the channel continues in an iterative fashion until the BER performance of the system is optimized.

In one embodiment, the adjustment made to the system includes increasing or decreasing the optical power level of the DWDM signal. The signal adjusted in accordance with the invention can be one of many optical carrier signals combined and transmitted over the single optical channel. The plural carrier signals are transmitted over the channel at different wavelengths and can be combined by WDM. Each of the individual optical signals can be adjusted and/or optimized in accordance with the invention.

Hence, in this aspect of the invention, an adjustment or optimization on a DWDM communication channel can be made based on actual errors in the data transmitted over the channel, such as by monitoring BER via the FEC portion of the data. This is in contrast to prior systems in which the data being transferred was not monitored and only the characteristics of the optical channel itself, e.g., OSNR, could be monitored and/or adjusted.

In accordance with the invention, the data can be carried on a time-division multiplexed (TDM) signal. The TDM signal can be a combination of multiple individual subsignals which can be combined by optical or electronic time-division multiplexing. The TDM signal can be generated, for example, in accordance with copending U. S. patent application Ser. No. 09/782,569, filed on Feb. 13, 2001, entitled, “Polarization Division Multiplexer,” assigned to the present assignee; and copending U.S. patent application Ser. No. 09/566,303, filed on May 8, 2000, entitled, “Bit Interleaved Optical Multiplexer,” also assigned to the present assignee. The contents of those applications are incorporated herein in their entirety by reference.

Each of the subsignals in the TDM signal can be formatted with its own FEC portion. At the transmit or input end of the channel, the DWDM equipment in accordance with the invention adds the FEC information to the subsignals. At the receive end, the DWDM equipment analyzes the FEC portion of each subsignal and generates and analyzes the error correction statistics, e.g., BER. Based on the statistics, an adjustment can be made to one or more of the subsignals as well as to the combined DWDM signal via the feedback signal sent to the input end of the channel via the control channel. The feedback signal can be a report or compilation of FEC statistics, such as BER, which is used at the transmit end to make adjustments to improve performance in response to the reported statistics.

In one embodiment, the power levels of individual subsignals can be adjusted such that they are balanced within the combined TDM signal. The balance can be achieved by adjusting the individual power levels until the error correction statistics indicate that the BERs for the subsignals are equal and optimized. That is, the signals can be adjusted in one embodiment such that the lowest BER rate with uniformity across the subsignals is achieved.

In another embodiment, the FEC statistics can be used to make adjustments at the receive end of the channel as well as at the transmit end. In this embodiment, if the error correction statistics indicate that an adjustment needs to be made, the adjustment may be made to the receive equipment. For example, the error statistics can be used to generate a control signal to adjust a decision circuit to reduce the errors in the data. By varying the bit decision threshold in one or more of the subsignal receiving systems, the error rate in each subsignal can be controlled. Again, this adjustment can be made to minimize and/or optimize BER in the subsignals and in the overall combined signal, such that, for example, the lower BER rate with uniformity across the subsignals is realized. In one particular embodiment, the receiver decision circuit adjustment is made every time a transmitter adjustment is made. For each transmitter adjustment, the receiver searches for a new decision threshold based on an optimization of BER using the FEC statistics.

In one embodiment, the adjustment can include altering the amount of FEC information added to the data. If the error correction statistics indicate errors above a predetermined threshold, more FEC information can be added to the data in order to reduce the errors, since increased FEC information results in increased error detection and correction capability. Thus, where the system provides for varying the amount of FEC information provided with the data, such as by specifying or altering a specified overhead percentage, the present invention provides for dynamically adjusting and optimizing the amount of FEC information, by providing feedback to the transmit end of the channel. Where, for example, it is reported by the receive end via the feedback that BER has increased, the transmit end may seek to correct the condition by varying, i.e., increasing, the amount of FEC in the transmitted data.

The DWDM system can receive the data for forwarding from any type of transmission system using any transmission protocol. For example, the data can be received from a SONET or ATM transmission system. The received data is then formatted by the DWDM equipment in accordance with the invention for forwarding over the DWDM transmission medium. This formatting includes adding the FEC portion of the data to the received data, configuring the data to be transmitted in the DWDM environment, e.g., adding the DWDM carrier to the data, and forwarding the DWDM signal over the transmission medium. At the receive end of the DWDM system, the signal is again processed in accordance with the invention. The optical DWDM signal is subject to an optical-to-electrical conversion, and the FEC portion of the data in the electrical domain is decoded. The error correction statistics are generated and processed, and the feedback signal based on the error correction statistics is generated and forwarded back to the input end of the channel where an adjustment can be made in response to the statistics, if desired. After the original data is processed and the added FEC information is removed, it can be forwarded on for further processing, by compatible service equipment, such as SONET, ATM or IP equipment. This can include electrical-to-optical conversion of the data, depending on the service equipment.

It should be noted that the invention can also process data received for processing which is already formatted with FEC information. This type of data can be used in accordance with the invention to adjust and/or optimize performance of the system. At the receive end of the channel, receive equipment compatible with the FEC information with the data analyzes the FEC information in accordance with the invention to generate the error correction statistics, which are then processed as described above in making adjustments to optimize performance. In this configuration, the system need not encode the data with additional FEC information.

In general, FEC can be in-band or out-of-band. In-band FEC used in SONET protocols has overhead bytes defined for FEC codes. Out-of-band FEC adds additional bytes to the protocol, e.g., SONET, by increasing the data rate. The out-of-band FEC is framed in a manner similar to SONET, that is, an overhead section and a payload section. In one embodiment of the invention, the FEC portion of the data is added to the data as out-of-band FEC.

The approach of the invention provides numerous advantages over other prior approaches to communication system monitoring and adjustment. For example, the present invention provides a means for optimizing the performance of a system, in particular, a DWDM system, using analysis of errors in the actual data being transferred. In contrast, prior systems could only monitor and adjust the channel optical characteristics such as OSNR. While it is important to maintain desirable OSNR levels, optimizing does not necessarily improve the performance of the system from the standpoint of bit errors. By adding FEC capability to the DWDM optical layer, the invention provides the capability to directly dynamically monitor actual system data transfer errors and adjust the system based on error rate performance. This results in far more reliable system transfer performance than was achievable in the prior systems.

### BACKGROUND OF THE INVENTION

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

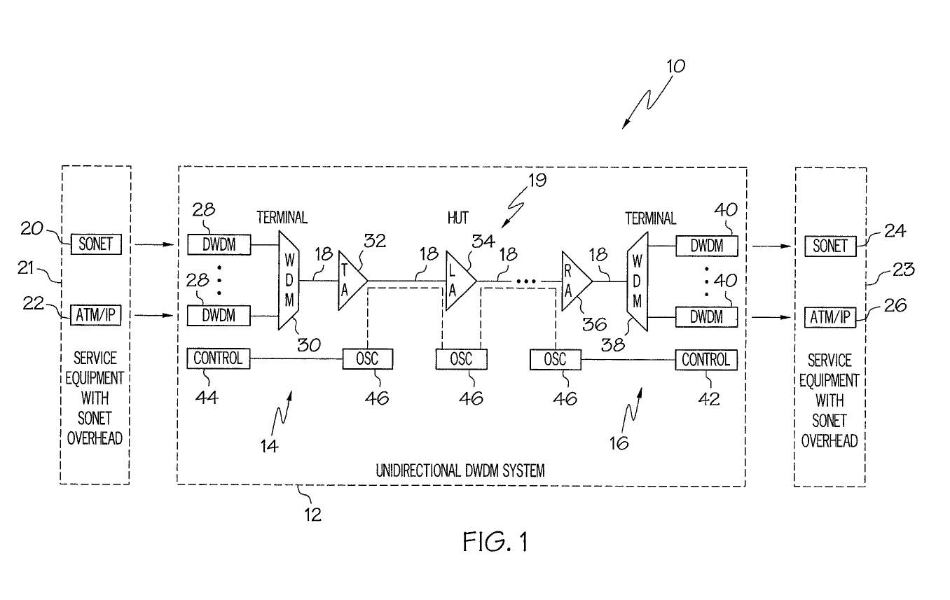

FIG. 1 contains a schematic functional block diagram of a data transport system with a dense wavelength-division multiplexed (DWDM) channel layer and an optical supervisory channel (OSC).

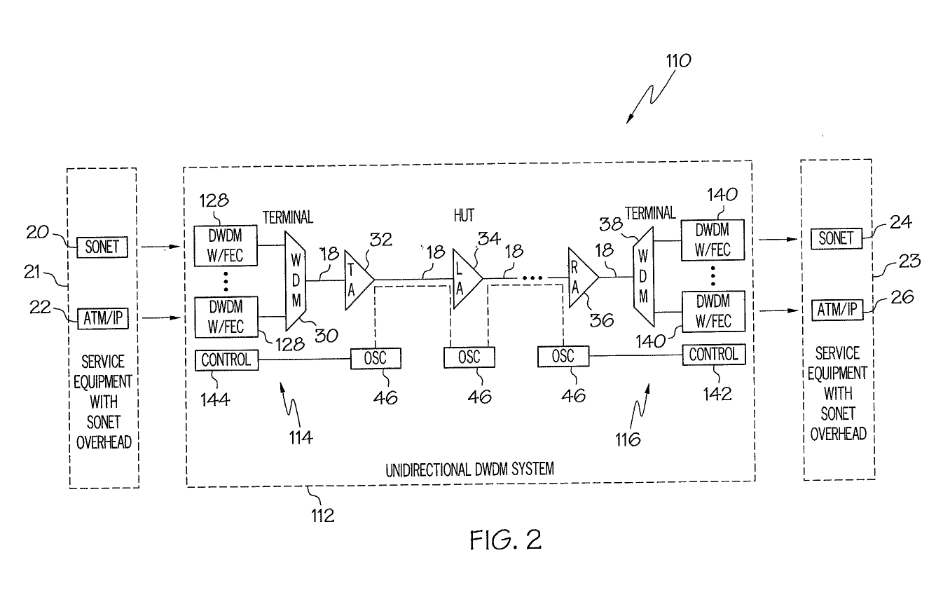

FIG. 2 contains a schematic functional block diagram of one embodiment of a data transport system with forward error correction (FEC) in the DWDM layer, in accordance with the invention.

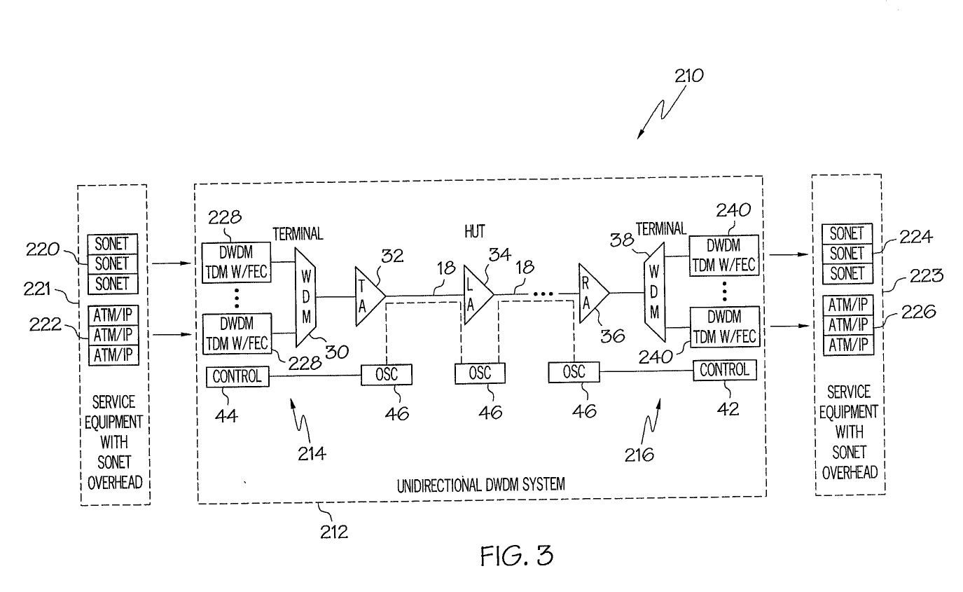

FIG. 3 contains a schematic functional block diagram of another embodiment of a data transport system with FEC in the DWDM layer and time-division multiplexing of signals, in accordance with the invention.

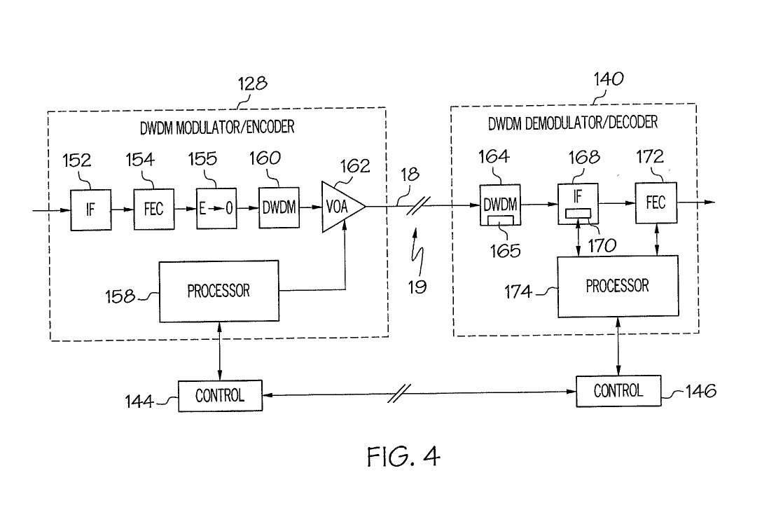

FIG. 4 contains a detailed schematic functional block diagram of the system of FIG. 2.

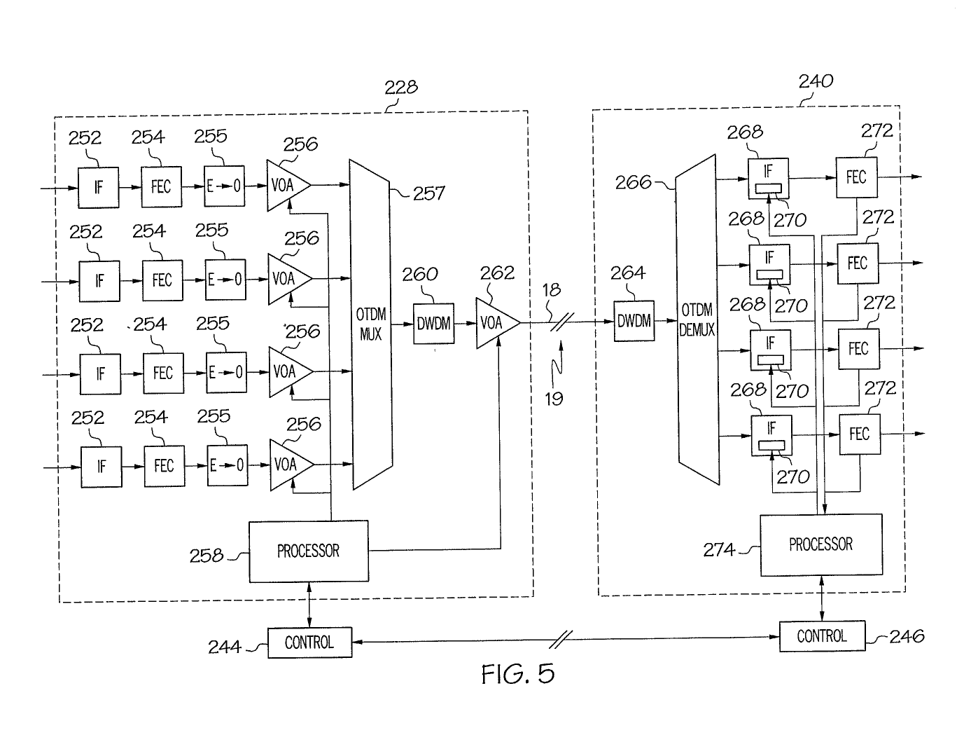

FIG. 5 contains a detailed schematic functional block diagram of one embodiment of the system of FIG. 3 in which individual subsignals are combined by optical time-division multiplexing.

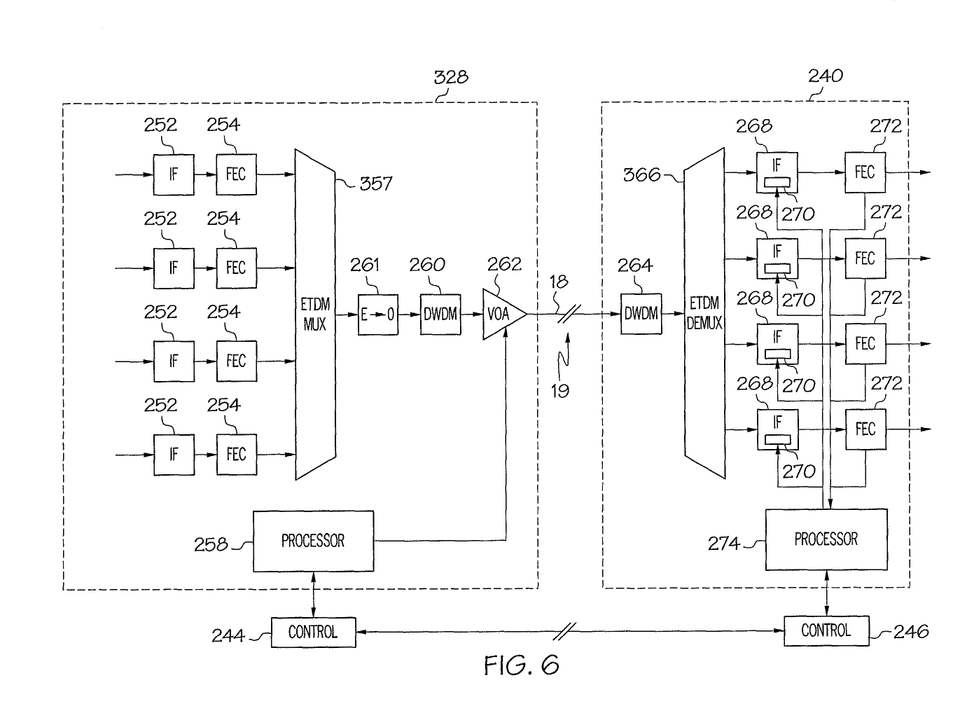

FIG. 6 contains a detailed schematic functional block diagram of another embodiment of the system of FIG. 3 in which individual subsignals are combined by electrical time-division multiplexing.

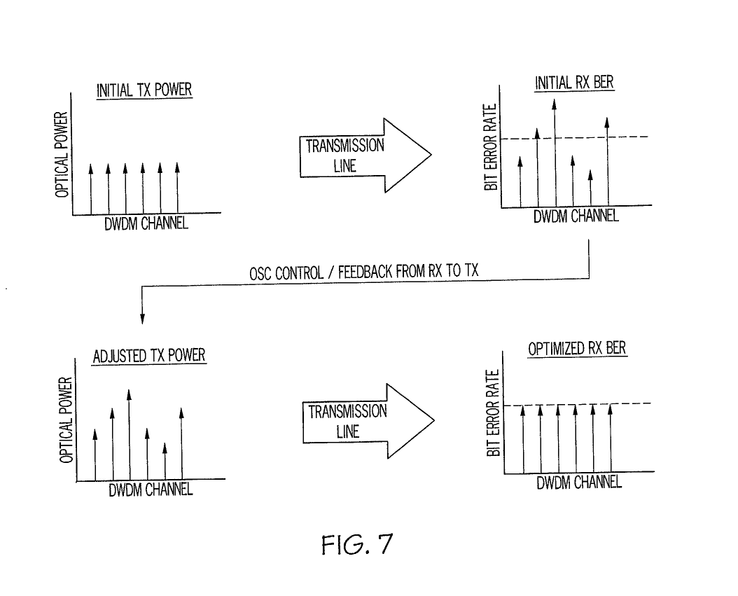

FIG. 7 contains a schematic diagram illustrating dynamic DWDM channel optimization in accordance with the invention.

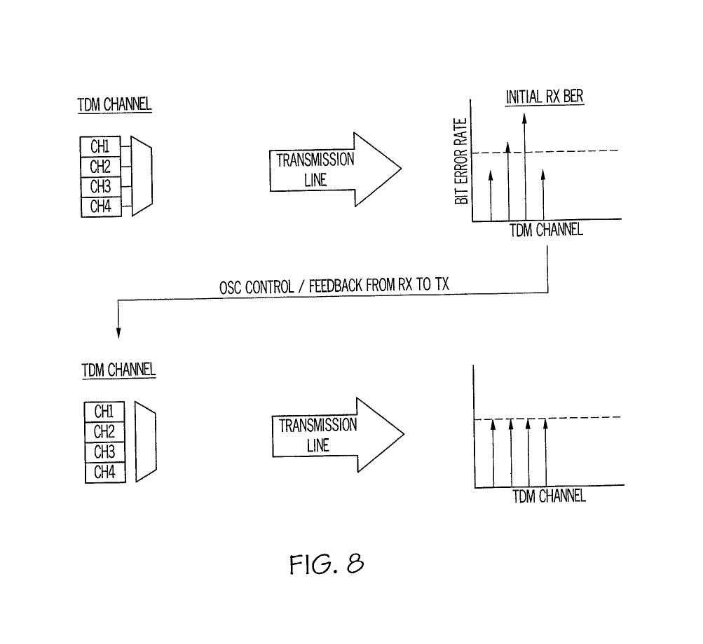

FIG. 8 contains a schematic diagram illustrating dynamic TDM channel optimization in accordance with the invention.

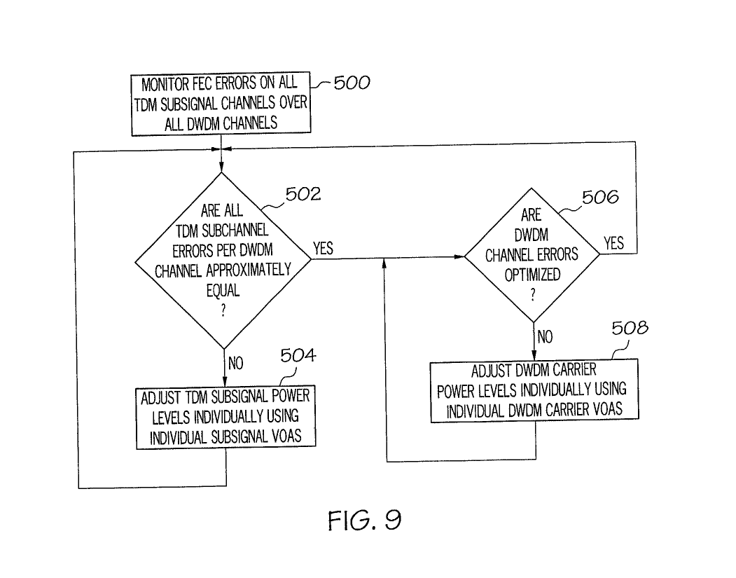

FIG. 9 contains a schematic flow chart illustrating one embodiment of dynamic communication channel optimization in accordance with the invention.

### DETAILED DESCRIPTION OF PREFERRED EMBODIMENTS OF THE INVENTION

FIG. 1 contains a schematic block diagram of an data transport system 10 in accordance with the invention. The system 10 includes a DWDM system 12 which forwards optical signals from input terminal equipment 14 to output terminal equipment 16 over an optical transport system 19 which includes optical fiber 18. Because the optical transport system 19 typically extends over long distances, i.e., many miles, it also includes multiple amplification stations or “huts” 34 which amplify and otherwise condition the optical signal. The DWDM system 12 receives inputs from any of various types of service equipment 21 which can include any type of data communication or telephony equipment. Examples of such equipment include SONET transmission equipment 20 and ATM transmission equipment 22 which transfers data in accordance with the IP protocol. The DWDM system 12 likewise provides output to service equipment 23, which can also be any kind of data communication or telephony equipment, such as SONET receiving equipment 24 and ATM receiving equipment 26.

In general, the input terminal equipment 14 includes multiple DWDM modulators/encoders 28. Each DWDM encoder 28 receives data from input service equipment 21, and the input data is used to modulate an optical signal in the DWDM encoder 28. Each of the encoders 28 forwards its respective optical signal to a wavelength-division multiplexer (WDM) 30 which combines the signals and outputs them in a single optical fiber channel. The signal is then conditioned and amplified by amplifier 32 and is forwarded onto the long-haul optical channel fiber 18.

At the output terminal equipment 16, a receiver 36 receives the optical signal, conditions and amplifies or attenuates the signal and forwards the conditioned signal on a fiber 18 to a WDM demultiplexer 38. The demultiplexer 38 separates the multiplexed optical signal into its original component wavelength carriers and outputs the original signals to DWDM demodulator/decoders 40. The DWDM demodulator/decoders 40 recover the original data signals from the DWDM optical carriers and forward the signals to the output service equipment 23.

The DWDM system 12 also includes an optical supervisory channel (OSC). The OSC provides for transmission of channel control messages on optical signals from the output terminal equipment 16 back to the input terminal equipment 14. In one embodiment, the OSC provides transmission of control messages along the fiber at a wavelength which prevents the OSC signals from interfering with the payload being carried in the DWDM signals at other wavelengths. An output terminal OSC controller 42 generates control messages and transfers the messages back along the OSC to the input terminal OSC controller 44. Thus, in accordance with the invention, the feedback adjust signal can be generated in the form of one or more messages transmitted from the receive end to the transmit end of the channel in accordance with any type of messaging protocol. In one embodiment of the invention, the messages transmitted along the OSC are formatted in accordance with the Ethernet protocol and are transferred over the OSC in accordance with the SONET protocol, i.e., the messages are transmitted using Ethernet over SONET. The messages can also be transferred in accordance with IP directly on the OSC. In will be understood that any form of messaging protocol can be used for sending the messages over the OSC in accordance with the invention. Additionally, any type of feedback signal sent back from the receive end to the transmit of the channel is compatible with the invention. Accordingly, the feedback adjust signal according to the invention could be a voltage level or logic level sent at the receive end and received at the transmit end of the channel. The OSC includes multiple OSC stations 46 which receive the OSC signal from the previous station analyze the signal and forward the signal to the next station 46, if required.

In SONET, ATM-IP and other systems, errors in data can be corrected using error correction protocols such as FEC. In the prior art systems, FEC is implemented in the SONET, ATM-IP or other layer external to the optical DWDM long-haul layer. Also, an approach to monitoring performance of a communication channel such as by monitoring bit error rate (BER) using FEC statistics is described in copending U.S. patent application Ser. No. 09/815,491 filed on Mar. 23, 2001, entitled “Intelligent Performance Monitoring in Optical Networks Using FEC Statistics,” assigned to the present assignee, the contents of which are incorporated herein by their entirety by reference.

In accordance with the present invention, FEC can be implemented within the optical DWDM layer. FIG. 2 is a schematic block diagram which illustrates this configuration of the invention. Using performance monitoring as described in the cop ending U.S. patent application Ser. No. 09/815,491, incorporated by reference above, data transfer characteristics such as bit error rate (BER) can be monitored within the optical DWDM layer.

In accordance with the invention, the FEC information used for error correction and performance monitoring is added to the incoming data at the input terminal equipment 14 located at the transmit end of the channel. The output terminal equipment 16 located at the receive end of the channel decodes and analyzes the FEC information and generates error correction statistics. The error correction statistics are analyzed to make a determination as to performance of the system, e.g., BER. A feedback signal is generated and forwarded along the OSC to the input terminal equipment 14. The feedback signal is based on the error correction statistics and may take the form of a report or compilation of error correction statistics.

In one embodiment, the feedback signal reports the BER calculated at the receive end using the FEC statistics. At the transmit end, the feedback signal is processed and analyzed to determine if an adjustment should be made to correct a condition reported by the output terminal equipment 16 at the receive end via the feedback signal. An adjustment may be made at the input terminal equipment 14; for example, transmitter power may be adjusted. Another feedback signal received at the transmit end from the receive end reports the effect of the adjustment. If an improvement is detected, then further adjustment of the same type may be made, e.g., the transmitter power may be further increased if improvement is shown following an initial increase. Conversely, if a decline in performance is observed, then another adjustment of a different type may be made, e.g., the transmitter power may be decreased where an initial power increase was followed by an increase in BER.

This process of adjusting at the transmit end based on feedback from the receive end can continue until performance is optimized. Also, it can be performed any time during operation of the system, not just at start-up, to ensure that system performance does not degrade. Continuous, dynamic optimization is realized by continuously monitoring error correction statistics and using them to make system adjustments where required.

As shown in FIG. 2, the DWDM modulator/encoders 128 include the addition of FEC information to the data before the individual DWDM carriers are multiplexed by the multiplexer 30. At the output terminal 116, the DWDM demodulator/decoders 140 receive the individual carriers and decode the FEC information.

As noted above, in accordance with another embodiment of the invention, the individual DWDM optical signals carry a time-division multiplexed combination of a plurality of subsignals. The subsignals can be electrically time-division multiplexed or optically time-division multiplexed in accordance with the invention. In this embodiment, each of the subsignals includes its own FEC information. FIG. 3 is a schematic block diagram which illustrates this embodiment of the invention. As shown in FIG. 3, each of the DWDM modulator/encoders 228 processes a TDM signal which includes FEC added to each of the subsignals. The output of each modulator/encoder 228 is forwarded to the wavelength-division multiplexer 30. At the output terminal equipment 216, the DWDM demodulator/decoders 240 receive the individual demultiplexed optical carriers and demodulate/decode the carriers to retrieve the TDM signals with FEC information added to the subsignals.

FIG. 4 is a schematic functional block diagram illustrating the details of the embodiment of the invention illustrated in FIG. 2, i,e, the embodiment in which the DWDM signal does not carry a TDM combination of multiple subsignals. The DWDM modulator/encoder 128 receives a signal at an interface 152. The interface 152 forwards the signal to an FEC encoder 154 which adds additional FEC information to the signal in accordance with the invention. The signal is then converted to the optical domain by electrical-to-optical converter or modulator 155. The modified optical signal is then forwarded to a DWDM circuit 160 which formats the signal for transmission in the DWDM optical layer of the system. The signal is then routed through another VOA 162 which is controllable to adjust the power level of the DWDM signal. The DWDM signal is then forwarded across the long-haul optical transport system 19 via fiber 18.

At the receive end, a DWDM receiver interface 164 receives the optical DWDM signal and retrieves the data signal from the DWDM carrier. The DWDM receiver interface includes optical-to-electrical conversion 165 to retrieve the original electrical signal with the FEC information. The signal is then forwarded to an interface circuit 168 which decodes and analyzes the data in the signal. The data signal is then forwarded to an FEC decoder circuit 172 which analyzes the additional FEC data added to the original signal in accordance with the invention. The signal is then transferred out of the DWDM demodulator/decoder 140.

The FEC statistics generated by the analysis in FEC decoder 172 are forwarded to a processor 174. In one embodiment, a report of the FEC statistics is generated by the processor 174 and is forwarded to the OSC controller 146. The FEC controller formats a message carrying the FEC statistics in accordance with some messaging protocol, such as Ethernet, SONET, IP, Ethernet-over-SONET, etc., and forwards the message over the OSC back to the input end OSC controller 144. The FEC statistics report data is forwarded to the processor 158 in the DWDM modulator/encoder 128. The statistics are analyzed to determine whether a condition exists in the system which should be corrected. For example if the BER is above a predetermined threshold, then it may be desirable to make an adjustment to the system, such as increasing optical power level of the DWDM signal being transmitted over the channel, to reduce BER.

Depending on the desired adjustment, a control signal can be routed to the VOA 162. The VOA 162 can be used to alter the power level of the final DWDM signal to be forwarded across the optical link.

In addition to feeding back the control signal to the transmission side of the channel, the processor 174 can also provide a signal for making adjustments at the receive end of the channel. Specifically, the interface circuit 168 which decodes the data signal includes a decision circuit 170. The decision circuit 170 applies the individual incoming data bits to a threshold to determine whether the bits should be interpreted as a mark or space, i.e., one or zero. Bit errors can be caused by the threshold in the decision circuit 170 being set at an improper level such that ones may be interpreted as zeros and vice versa. The control signal can be sent by the processor 174 to the decision circuit 170 to alter the decision threshold in order to reduce or minimize the BER detected.

The above adjustments, namely, the feedback signal to control transmitted signal power and the decision circuit threshold adjustment, can be made periodically or continuously such that dynamic optimization of the system can be achieved. The VOA 162 can be adjusted in order to optimize system performance based on BER. The VOA 162 can be adjusted to alter the power level of the DWDM signal such that attributes such as OSNR can be improved, resulting in improvement in BER.

FIG. 5 contains a schematic detailed block diagram illustrating details of the embodiment of the invention illustrated in FIG. 3, i.e., the embodiment in which the DWDM signal carries a TDM combination of multiple subsignals. In this particular embodiment, the signal carried in the DWDM layer is an optically time-division multiplexed combination of individual subsignals. In one embodiment, each subsignal is an OC-192 signal at approximately 10 Gb/sec. In one embodiment, as illustrated in FIG. 5, four such subsignals are optically time-division multiplexed by a OTDM MUX 257 into a single signal at approximately 40 Gb/sec. Each individual subsignal is received at the DWDM modulator/encoder 228 by an interface circuit 252. In accordance with the invention, additional FEC information is added to the subsignals by FEC encoders 254. The modified subsignals are then converted to optical signals by electrical-to-optical converters or modulators 255, and the converted optical signals are then forwarded to VOAs 256. The signals are then multiplexed by the OTDM MUX 257 such as by the approach described in copending U.S. patent application Ser. Nos. 09/566,303 and 09/782,569, incorporated by reference above. The OTDM signal is then forwarded to a DWDM circuit 260 which formats the signal for transmission over the optical transport system 19 in the DWDM layer. The signal is forwarded to the optical channel 19 through another VOA 262 capable of adjusting the optical power level of the individual DWDM carrier signal. It will be understood that this configuration is repeated for each wavelength signal in the overall combined DWDM signal transferred over the channel 19.

At the receive end of the channel, the signal is received by a DWDM circuit 264 which performs and optical-to-electrical conversion and recovers the TDM signal from the optical DWDM carrier. The TDM signal is then forwarded to a OTDM demultiplexer 266 which recovers the four original subsignals with additional FEC information. The signals are forwarded to interface circuits 268 which include decision circuits 270. The interface circuits 268 decode the data and forward the data to FEC analysis circuits 272. The FEC circuits 272 analyze the FEC data to generate the FEC statistics and forward the statistics to the processor 274. The original transmitted data is then forwarded on for further processing. The processor 274 receives the statistics and generates a feedback signal message reporting the statistics and sends it back to the input end of the channel via the optical supervisory channel (OSC) controller 246. The controller 246 forwards the OSC signal to the input OSC controller 244 which forwards the signal to the input terminal processor 258. The processor 258 then provides the signals required to make the necessary adjustments.

Each VOA 256 can be adjusted individually to adjust the power levels of the subsignals separately. This can be done to balance the power levels of the subsignals such that they are equal within the TDM signal. It can also be done to separately minimize BER in each subsignal individually. Also, the VOA 262 can be controlled to adjust the power level of the DWDM signal 260 as it is transmitted from the input terminal equipment. Again, this adjustment can be made to improve OSNR such that overall BER of the system is improved. Also, this adjustment can be made to each individual optical carrier signal within the combined multiple-wavelength DWDM signal. This can be done to balance the BERs of all of the DWDM optical channels within the combined DWDM signal. Also, at the output terminal end of the system, the thresholds in each of the decision circuits 270 for each of the subsignal channels can be adjusted individually to minimize or optimize individual and/or overall system BER.

FIG. 6 contains a detailed schematic functional block diagram of another embodiment of the system of FIG. 3 in which individual subsignals are combined by electrical time-division multiplexing, in contrast to the system of FIG. 5 in which optical TDM is used. The configuration of FIG. 6 is similar to that of FIG. 5; accordingly, description of features common to both configurations is omitted to avoid repetition.

In the system of FIG. 6, FEC information is added to the input signals by FEC circuits 254, and the resulting individual subsignals are combined into a TDM signal by ETDM MUX 357, such as by the approach described in copending U.S. patent application Ser. Nos. 09/566,303 and 09/782,569, incorporated by reference above. The ETDM signal is converted to an optical signal by an electrical-to-optical converter or modulator 261, and the converted optical signal is then forwarded to a DWDM circuit 260 which formats the signal for transmission over the optical transport system 19 in the DWDM layer. The signal is forwarded to the optical channel 19 through a VOA 262 capable of adjusting the optical power level of the individual DWDM carrier signal. It will be understood that this configuration is repeated for each wavelength signal in the overall combined DWDM signal transferred over the channel 19.

Hence, the system of the invention provides an approach to adjusting and/or optimizing performance of the communication channel based on actual data errors. The approach provides the capability to monitor errors within the optical DWDM layer and make adjustments both inside the DWDM layer and outside the layer to improve error performance. The characteristics of the original signal can be altered based on error performance as can the individual subsignals within the TDM data signal. This flexibility results in a system with greatly improved system performance from the standpoint of data errors.

FIG. 7 is a schematic diagram which illustrates an approach to dynamically optimizing a DWDM channel which carries multiple WDM signals combined into a single signal. The top diagram in FIG. 7 illustrates the initial condition in which all of the optical DWDM signal transmitters are set to the same power level. In this illustration, six individual DWDM optical carriers are illustrated. The signals are transmitted in WDM format across the transmission line to the output end. Bit error rate (BER) at the receive end for the DWDM channel is analyzed. As shown, the BER for the individual DWDM signals vary. In accordance with the invention, it may be determined that the BERs for the individual DWDM signals should be balanced. In accordance with the invention, error correction statistics can be sent along the OSC control channel from the receive end to the transmit end to enable an adjustment to the transmit power, such as by adjusting a variable optical attenuator 162 (FIG. 4) or 262 (FIGS. 5 and 6). It will be understood that each individual DWDM carriers is associated with a DWDM modulator/encoder 128, 228 as well as a DWDM demodulator/decoder 140, 240. To adjust the level of a particular selected DWDM carrier based on the detected BER, the control signal is sent to the VOA 262 in the appropriate associated modulator/encoder 128, 228. As illustrated in FIG. 7, at the input end, the individual DWDM carrier transmit powers are adjusted within the DWDM channels, such as by adjusting the VOAs 162, 262. As a result, the DWDM channel is optimized, that is, the BERs of the individual DWDM signals are balanced at the output end of the channel.

FIG. 8 is a schematic diagram which illustrates dynamic TDM channel optimization in accordance with the invention. In this aspect of the invention, the signal transmitted is an optical or electronic TDM combination of multiple subchannels, in this example, four subchannels. Referring to FIGS. 5 and 8, the individual channels, CH1-CH4 are multiplexed together by the TDM MUX 257 and forwarded over the transmission line to the receive end of the channel. Initially, the BER measurements fed back over the OSC indicate that the TDM subsignals are not balanced within the TDM signal, that is, the BERs are not equal or optimized. In response, in accordance with the invention, the individual VOAs 256 are adjusted within the DWDM modulator/encoder 228 of the invention. The individual subsignal power levels are adjusted such that, as shown in FIG. 8, at the output end of the channel, BER within the TDM signal channel is optimized. That is, the BERs for the individual subsignals are balanced.

FIG. 9 contains a schematic flow chart of one approach to dynamic optimization of a communication channel in accordance with an embodiment of the present invention. As indicated by step 500, FEC errors are monitored on all of the TDM subsignal channels over all of the DWDM optical carrier channels. In step 502, the TDM subchannel errors as indicated by the FEC error statistics are analyzed. If the errors across the subchannels are approximately equal on each of the DWDM carrier channels, then flow continues out of the “yes” branch of the decision block 502. If they are not equal, then, in step 504, the TDM subsignal power levels are adjusted individually using the individual subsignal VOAs 256 as described above in connection with FIG. 5. Flow returns to the top where in step 502 the individual TDM subsignal channel errors are monitored.

When the TDM subsignal and channel errors are equal, the DWDM channel errors are optimized. In decision block 506, it is determined whether the DWDM channel errors are optimized. As described above, optimized DWDM channel errors can mean that the errors in each individual DWDM optical carrier channel are equal, based on the analysis of the FEC error statistics. If the DWDM channel errors are optimized, then flow returns to decision 502, where the individual TDM subsignal channels are continuously checked to ensure that the BERs across the channels are approximately equal. If in decision block 506 it is determined that the DWDM channel errors are not optimized, then, in step 508, the feedback signal is sent to the DWDM carrier VOAs 162, 262 to adjust the power levels of the individual DWDM optical carriers. The errors on the individual DWDM carrier signals are checked again in decision box 506 to determine whether the errors are optimized across all of the DWDM channels. When the errors are optimized, flow returns to the top of decision block 502.

The foregoing description describes making adjustments to a communication channel to adjust and/or optimize performance of the channel based on measures of performance obtained from FEC error correction statistics. In the specific embodiments described heretofore, the adjustments made at the transmit end of the channel were described as only including power adjustments. It will be understood that the invention encompasses any adjustments made to the system to adjust or optimize performance.

In accordance with the invention, many adjustments can be made at the transmit end of the channel in response to the error statistics reported via the feedback from the receive end of the channel. For example, wavelength alignment may be adjusted. This can be done by temperature tuning a laser source wavelength or a WDM filter to achieve proper wavelength alignment within the WDM signal.

Also, the dc bias and RF power to an optical modulator may by adjusted to achieve the optimal extinction ratio. Also, the optical pulse width can be adjusted by applying various power levels of one or more RF frequencies and dc bias to change the pulse width of an optical Rz clock. Optical chirp can be adjusted by changing the RF power balance into E/O modulators for either data modulation with chirp or clock generation with chirp. Receiver phase alignment can be adjusted by adjusting RF phase and dc bias for the alignment of RZ data pulses with a switching window of an optical demultiplexer. Transmitter phase alignment can be adjusted by adjusting RF phase and dc bias for the alignment of RZ data pulses with a data window for RZ data modulation. In accordance with the invention, the FEC error correction, e.g., BER, information can be used to trigger protection switching due to signal degrade or signal fail conditions set by BER thresholds.

In accordance with the invention, the FEC error correction statistics can be used to optimize dispersion of a tunable dispersion compensator used for individual or composite DWDM signals. The statistics can also be used to optimize power and gain equalization using dynamic gain equalization or dynamic gain flattening filter technologies. They can also be used in accordance with the invention to optimize tunable tilt compensation technologies and to optimize polarization mode dispersion compensation.

While this invention has been particularly shown and described with references to preferred embodiments thereof, it will be understood by those skilled in the art that various changes in form and details may be made therein without departing from the spirit and scope of the invention as defined by the following claims.

1. A method of adjusting performance of a communication system, the communication system having at least one communication channel, data being forwarded over each communication channel from an input end of the communication channel to an output end of the communication channel, the method comprising:
forwarding data from an input end to an output end of a first communication channel;
using a forward error correction (FEC) portion of the data, determining if an error has occurred in the data;
monitoring error correction statistics related to errors detected in the data; and
using the error correction statistics, generating an adjust signal to make an adjustment in the communication system to adjust performance of the communication system.

2. The method of claim 1, wherein the adjust signal is a feedback signal sent from the output end of the communication channel to the input end of the communication channel.

3. The method of claim 2, wherein the feedback signal is sent on a control channel associated with the communication channel.

4. The method of claim 3, wherein the adjust signal comprises a communication message formatted in accordance with a communication protocol.

5. The method of claim 1, wherein the adjust signal comprises a communication message formatted in accordance with a communication protocol.

6. The method of claim 1, wherein the error correction statistics include bit error rate (BER) for the data.

7. The method of claim 1, wherein the data comprises a combined signal generated by combining a plurality of subsignals.

8. The method of claim 7, wherein the combined signal is a time-division multiplexed (TDM) combination of the subsignals.

9. The method of claim 7, wherein the combined signal is an optical time-division multiplexed (TDM) combination of the subsignals.

10. The method of claim 7, wherein the combined signal is an electrical time-division multiplexed (TDM) combination of the subsignals.

11. The method of claim 7, wherein the FEC portion of the data is added to at least one of the subsignals.

12. The method of claim 7, wherein the adjust signal is generated to make an adjustment in the combined signal.

13. The method of claim 12, wherein the adjustment includes adjusting a power level of the combined signal.

14. The method of claim 7, wherein the adjust signal is generated to make an adjustment in at least one of the subsignals.

15. The method of claim 14, wherein the adjustment includes adjusting a power level of at least one of the subsignals.

16. The method of claim 7, wherein the combined signal is an optical wavelength-division multiplexed (WDM) signal.

17. The method of claim 1, wherein the data comprises an optical wavelength-division multiplexed (WDM) signal.

18. The method of claim 17, wherein the FEC portion of the data is added to the optical WDM signal.

19. The method of claim 17, wherein the optical WDM signal includes a time-division multiplexed (TDM) signal including a plurality of TDM subsignals.

20. The method of claim 17, wherein the adjust signal is generated to make an adjustment in the WDM signal.

21. The method of claim 20, wherein the adjustment includes adjusting a power level of the WDM signal.

22. The method of claim 1, wherein the data is received for forwarding from a transmission device which forwards data in accordance with the standard SONET protocol.

23. The method of claim 22, wherein the data received from the transmission device comprises one or more standard SONET frames.

24. The method of claim 23, wherein the FEC portion of the data is added to the one or more standard SONET frames before the data is forwarded on the communication channel.

25. The method of claim 1, wherein each of the subsignals includes a portion of the FEC portion of the data.

26. The method of claim 1, wherein the adjustment comprises altering an amount of information in the FEC portion of the data.

27. The method of claim 1, wherein the adjust signal is used in making an adjustment at the input end of the communication channel.

28. The method of claim 1, wherein the adjust signal is used in making an adjustment at the output end of the communication channel.

29. A communication system with adjustable performance, comprising:
at least one communication channel, data being forwarded over each communication channel from an input end of the communication channel to an output end of the communication channel;
a processor for (i) using a forward error correction (FEC) portion of the data, determining if an error has occurred in the data, (ii) monitoring error correction statistics related to errors detected in the data, and (iii) using the error correction statistics, generating an adjust signal to make an adjustment in the communication system to adjust performance of the communication system.

30. The method of claim 29, wherein the adjust signal is a feedback signal sent from the output end of the communication channel to the input end of the communication channel.

31. The communication system of claim 30, further comprising a control channel associated with the communication channel, the feedback signal being sent on the control channel.

32. The communication system of claim 31, wherein the adjust signal comprises a communication message formatted in accordance with a communication protocol.

33. The communication system of claim 29, wherein the adjust signal comprises a communication message formatted in accordance with a communication protocol.

34. The communication system of claim 29, wherein the error correction statistics include bit error rate (BER) for the data.

35. The communication system of claim 29, wherein the data comprises a combined signal generated by combining a plurality of subsignals.

36. The communication system of claim 35, wherein the combined signal is a time-division multiplexed (TDM) combination of the subsignals.

37. The communication system of claim 35, wherein the combined signal is an optical time-division multiplexed (TDM) combination of the subsignals.

38. The communication system of claim 35, wherein the combined signal is an electrical time-division multiplexed (TDM) combination of the subsignals.

39. The communication system of claim 35, wherein the FEC portion of the data is added to at least one of the subsignals.

40. The communication system of claim 35, wherein the adjust signal is generated to make an adjustment in the combined signal.

41. The communication system of claim 40, wherein the adjustment includes an adjustment to a power level of the combined signal.

42. The communication system of claim 35, wherein the adjust signal is generated to make an adjustment in at least one of the subsignals.

43. The communication system of claim 42, wherein the adjustment includes an adjustment to a power level of at least one of the subsignals.

44. The communication system of claim 35, wherein the combined signal is an optical wavelength-division multiplexed (WDM) signal.

45. The communication system of claim 29, wherein the data comprises an optical wavelength-division multiplexed (WDM) signal.

46. The communication system of claim 45, wherein the FEC portion of the data is added to the optical WDM signal.

47. The communication system of claim 45, wherein the optical WDM signal includes a time-division multiplexed (TDM) signal including a plurality of TDM subsignals.

48. The communication system of claim 45, wherein the adjust signal is generated to make an adjustment in the WDM signal.

49. The communication system of claim 48, wherein the adjustment includes an adjustment to a power level of the WDM signal.

50. The communication system of claim 29, wherein the data is received for forwarding from a transmission device which forwards data in accordance with the standard SONET protocol.

51. The communication system of claim 50, wherein the data received from the transmission device comprises one or more standard SONET frames.

52. The communication system of claim 51, wherein the FEC portion of the data is added to the one or more standard SONET frames before the data is forwarded on the communication channel.

53. The communication system of claim 29, wherein each of the subsignals includes a portion of the FEC portion of the data.

54. The communication system of claim 29, wherein the adjustment comprises altering an amount of information in the FEC portion of the data.

55. The communication system of claim 29, wherein the adjust signal is used in making an adjustment at the input end of the communication channel.

56. The communication system of claim 29, wherein the adjust signal is used in making an adjustment at the output end of the communication channel.

57. A communication channel comprising:
a wavelength-division multiplexed (WDM) optical layer channel within the communication channel;
a WDM transmission subsystem at a transmit end of the WDM optical layer channel for formatting data to be transmitted on the WDM optical layer channel in a WDM format, the WDM transmission subsystem including a forward error correction (FEC) encoding system for adding FEC information to the data;
a WDM reception subsystem at a receive end of the WDM optical layer channel for receiving data transmitted on the WDM optical layer channel in the WDM format, the WDM subsystem including an FEC decoding system for analyzing the FEC information added to the data; and
a processor for analyzing error correction statistics associated with the analyzed FEC information and using the error correction statistics to identify a condition in the communication channel.
